(19) United States
(12) Patent Application Publication
(10) Pub. No.: US 2019/0246053 A1
(43) Pub. Date: Aug. 8, 2019

(54) Motion tracking using multiple exposures

(71) Applicant: INVISAGE TECHNOLOGIES, INC., Newark, CA (US)

(72) Inventors: Zachary M. Beiley, Oakland, CA (US); Gregory Chow, Mountain View, CA (US); Naveen Kolli, Fremont, CA (US)

(21) Appl. No.: 16/341,902

(22) PCT Filed: Oct. 22, 2017
(86) PCT No.: PCT/US2017/057766

§ 371 Date: Apr. 14, 2019

Related U.S. Application Data
(60) Provisional application No. 62/411,515, filed on Oct. 21, 2016.

(51) Int. Cl. H04N 5/353; H04N 5/374; H04N 5/369; H04N 5/378

(52) U.S. Cl. CPC H04N 5/3535; H04N 5/378; H04N 5/379; H04N 5/374

(57) ABSTRACT

Imaging apparatus (100, 200) includes a photosensitive medium (304) configured to convert incident photons into charge carriers and a common electrode (306), which overlies the photosensitive medium and is configured to apply a bias potential to the photosensitive medium. An array (202) of pixel circuits (302) is formed on a semiconductor substrate (312). Each pixel circuit defines a respective pixel (212) and collects the charge carriers from the photosensitive medium while the common electrode applies the bias potential and to output a signal responsively to the collected charge carriers. Control circuitry (208) reads out the signal from the pixel circuits in each of a periodic sequence of readout frames (500) and drives the common electrode to apply the bias potential to the photosensitive medium during each of a plurality of distinct shutter periods (506, 702, 704, 902, 904) within at least one of the readout frames.

### CROSS-REFERENCE TO RELATED APPLICATION

This application claims the benefit of U.S. Provisional Patent Application 62/411,515, filed Oct. 21, 2016, which is incorporated herein by reference.

### FIELD OF THE INVENTION

The present invention relates generally to methods and devices for image sensing, and particularly to sensing motion using film-based image sensors.

### BACKGROUND

In film-based image sensors, a silicon-based switching array is overlaid with a photosensitive film such as a film containing a dispersion of quantum dots. Films of this sort are referred to as “quantum films.” The switching array, which can be similar to those used in complementary metal-oxide sandwich (CMOS) image sensors that are known in the art, is coupled by suitable electrodes to the film in order to read out the photocharge that accumulates in each pixel of the film due to incident light.

U.S. Pat. No. 7,923,801, whose disclosure is incorporated herein by reference, describes materials, systems and methods for optoelectronic devices based on such quantum films.

### SUMMARY

Embodiments of the present invention that are described hereinbelow provide enhanced image sensor designs and methods for operation of image sensors with enhanced performance.

There is therefore provided, in accordance with an embodiment of the invention, imaging apparatus, including a photosensitive medium configured to convert incident photons into charge carriers and a common electrode, which is at least partially transparent, overlying the photosensitive medium and configured to apply a bias potential to the photosensitive medium. An array of pixel circuits is formed on a semiconductor substrate. Each pixel circuit defines a respective pixel and is configured to collect the charge carriers from the photosensitive medium while the common electrode applies the bias potential and to output a signal responsively to the collected charge carriers. Control circuitry is configured to read out the signal from the pixel circuits in each of a periodic sequence of readout frames and to drive the common electrode to apply the bias potential to the photosensitive medium during each of a plurality of distinct shutter periods within at least one of the readout frames.

In a disclosed embodiment, the photosensitive medium includes a quantum film.

In one embodiment, the plurality of the distinct shutter periods includes at least a first shutter period and a second shutter period of equal, respective durations. Alternatively, the first shutter period and second shutter period have different, respective durations.

In some embodiments, the photosensitive medium includes a first photosensitive layer, which is configured to convert the incident photons in a first wavelength band into the charge carriers, and a second photosensitive layer, which is configured to convert the incident photons in a second wavelength band, different from the first wavelength band, into the charge carriers. The control circuitry is configured to drive the common electrode to apply the bias potential only to the first photosensitive layer during a first shutter period and to apply the bias potential only to the second photosensitive layer during a different, second shutter period among the plurality of distinct shutter periods within the at least one of the readout frames.

In a disclosed embodiment, the first wavelength band is a visible wavelength band, while the second wavelength band is an infrared wavelength band.

The first and second photosensitive layers may both be overlaid on a common set of the pixel circuits, which collect the charge carriers in response to the photons that are incident during both of the first and second shutter periods. Alternatively, the first and second photosensitive layers are overlaid on different, respective first and second sets of the pixel circuits.

In a disclosed embodiment, the control circuitry is configured to synchronize the shutter periods with a pulsed illumination source, which illuminates a scene while an image of the scene is captured by the apparatus.

In some embodiments, the control circuitry is configured to process the signal in the at least one of the readout frames so as to identify, responsively to the plurality of the distinct shutter periods, a moving object in an image captured by the apparatus. In one embodiment, the control circuitry is configured to estimate a velocity of the moving object responsively to a distance between different locations of the moving object that are detected respectively during the distinct shutter periods.

There is also provided, in accordance with an embodiment of the invention, a method for imaging, which includes overlaying a common electrode, which is at least partially transparent, on a photosensitive medium configured to convert incident photons into charge carriers. An array of pixel circuits, each defining a respective pixel, is coupled to collect the charge carriers from the photosensitive medium while the common electrode applies a bias potential to the photosensitive medium and to output a signal responsively to the collected charge carriers. The signal is read out from the pixel circuits in each of a periodic sequence of readout frames. The common electrode is driven to apply the bias potential to the photosensitive medium during each of a plurality of distinct shutter periods within at least one of the readout frames.

There is additionally provided, in accordance with an embodiment of the invention, imaging apparatus, including a photosensitive medium configured to convert incident photons into charge carriers. Pixel circuitry is coupled to the photosensitive medium and configured to create one or more imprints of an object in an image that is formed on the photosensitive medium, wherein each of the imprints persists over one or more image frames.

The present invention will be more fully understood from the following detailed description of the embodiments thereof, taken together with the drawings in which:

### BRIEF DESCRIPTION OF THE DRAWINGS

FIG. 1 is a schematic side view of a camera module, which is operative in accordance with an embodiment of the invention;

FIG. 2 is a schematic top view of an example image sensor, in accordance with an embodiment of the invention;

FIGS. 3A-3C are schematic sectional side views of example pixels of image sensors in accordance with embodiments of the invention;

FIGS. 4A and 4B are electrical circuit diagrams that schematically illustrate pixel circuits in an image sensor, in accordance with embodiments of the invention;

FIG. 5 is a signal timing diagram that schematically illustrates the operation of an image sensor with a global shutter, in accordance with an embodiment of the invention;

FIG. 6 is a schematic representation of an image captured by an image sensor using two shutter periods in a readout frame, in accordance with an embodiment of the invention;

FIG. 7 is a signal timing diagram that schematically illustrates the operation of an image sensor with a global shutter, in accordance with another embodiment of the invention;

FIG. 8 is a schematic representation of images of an object captured by an image sensor using two unequal shutter periods in a readout frame, in accordance with an embodiment of the invention;

FIG. 9 is a signal timing diagram that schematically illustrates the operation of an image sensor with a global shutter in synchronization with a pulsed illumination source, in accordance with another embodiment of the invention;

FIGS. 10A and 10B are schematic sectional and top views, respectively, of a group of pixels in an image sensor with multiple photosensitive layers, in accordance with an embodiment of the invention;

FIG. 11 is a signal timing diagram that schematically illustrates the operation of an image sensor with separate global shutters for different photosensitive layers, in accordance with another embodiment of the invention;

FIG. 12 is a schematic representation of images captured by the image sensor of FIGS. 10A/B upon application of the signals shown in FIG. 11, in accordance with an embodiment of the invention;

FIG. 13 is a schematic top view of an image sensor in which different photosensitive layers are overlaid on different, respective sets of pixel circuits, in accordance with another embodiment of the invention;

FIG. 14 is a signal timing diagram that schematically illustrates the operation of an image sensor with photosensitive layers and global shutters synchronized in both time and wavelength with a pulsed illumination source, in accordance with another embodiment of the invention;

FIGS. 15A and 15B are electrical band diagrams showing potential distributions within a photosensitive medium under different bias voltage conditions, in accordance with an embodiment of the invention; and

FIG. 16 is a signal timing diagram that schematically illustrates the operation of an image sensor in capturing imprints over multiple frames, in accordance with an embodiment of the invention.

### DETAILED DESCRIPTION OF EMBODIMENTS

### System Overview

The image sensors described herein may be used within any suitable imaging device, such as a camera, spectrometer, light sensor, or the like. FIG. 1 shows one example of a camera module 100 that may utilize an image sensor 102, which may be configured in any manner as described below. Camera module 100 may comprise a lens system 104, which may direct and focus incoming light onto image sensor 102. While depicted in FIG. 1 as a single element, it should be appreciated that lens system 104 may actually include a plurality of lens elements, some or all of which may be fixed relative to each other (e.g., via a lens barrel or the like). Camera module 100 may optionally be configured to move lens system 104 and/or image sensor 102 to perform autofocus and/or optical image stabilization.

The camera module may further comprise one or more optional filters, such as a filter 106, which may be placed along the optical path. Filter 106 may reflect or otherwise block certain wavelengths of light, and may substantially prevent, based on the effectiveness of the filter, these wavelengths of light from reaching image sensor 102. As an example, when an image sensor is configured to measure visible light, filter 106 may comprise an infrared cutoff filter. While shown in FIG. 1 as being positioned between image sensor 102 and lens system 104, filter 106 may be positioned to cover lens system 104 (relative to incoming light) or may be positioned between lenses of lens system 104.

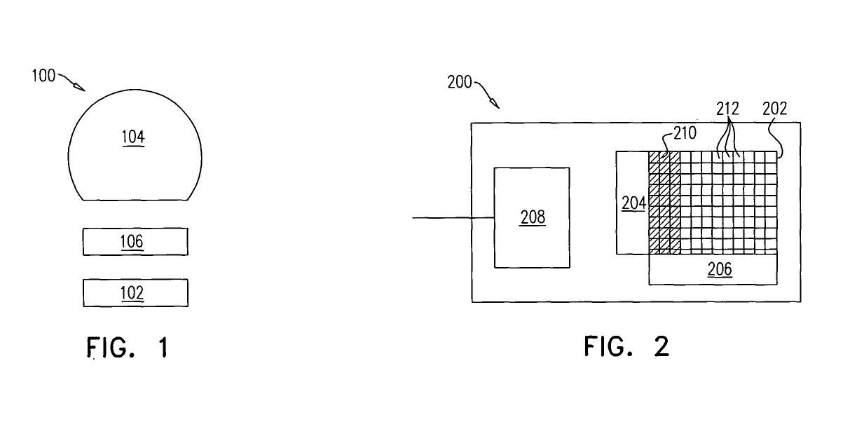

FIG. 2 shows a top view of an exemplary image sensor 200 as described herein. Image sensor 200 may comprise an imaging area comprising a pixel array 202, which may include a first plurality of pixels 212 comprising a photosensitive medium, such as a quantum film, that may be used to convert incident light into electrical signals. Each pixel 212 is defined by a corresponding pixel circuit (also referred to as pixel circuitry), formed on a semiconductor substrate, as described further hereinbelow. In some instances, pixel array 202 may comprise an obscured region 210 including at least one pixel (e.g., a second plurality of pixels) that is obscured relative to incoming light (e.g., covered by a light-blocking layer). Electrical signals may still be read out from some or all of these pixels, but since there is ideally no light reaching these pixels, the current measured from these pixels may represent the dark current associated with one or more components of the image sensor. Image sensor 200 (or associated processing circuitry) may compensate for the dark current levels during image capture and/or processing.

Image sensor 200 may further comprise row circuitry 204 and column circuitry 206, which collectively may be used to convey various signals (e.g., bias voltages, reset signals) to individual pixels as well as to read out signals from individual pixels. For example, row circuitry 204 may be configured to simultaneously control multiple pixels in a given row, while column circuitry 206 may convey pixel electrical signals to other circuitry for processing. Accordingly, image sensor 200 may comprise control circuitry 208, which may control the row circuitry 204 and column circuitry 206, as well as performing input/output operations (e.g., parallel or serial IO operations) for image sensor 200.

In particular, in the embodiments that are described hereinbelow, control circuitry 208 reads out the signals from the pixel circuits in pixels 212 in each of a periodic sequence of readout frames, while driving array 202 to apply a global shutter to the pixels during each of a plurality of distinct shutter periods within one or more of the readout frames. The control circuitry may include a combination of analog circuits (e.g., circuits to provide bias and reference levels) and digital circuits (e.g., image enhancement circuitry, line buffers to temporarily store lines of pixel values, register banks that control global device operation and/or frame format).

Additionally or alternatively, control circuitry 208 may be configured to perform higher-level image processing functions on the image data output by pixel array 202. For this purpose, in some embodiments, control circuitry 208 comprises a programmable processor, such as a microprocessor or digital signal processor, which can be programmed in software to perform image processing functions. For example, such a processor can be programmed to detect motion in image frames, as described hereinbelow. Alternatively, such processing functions can be performed by a separate computer or other image processor (not shown in the figures), which receives image data from image sensor 200.

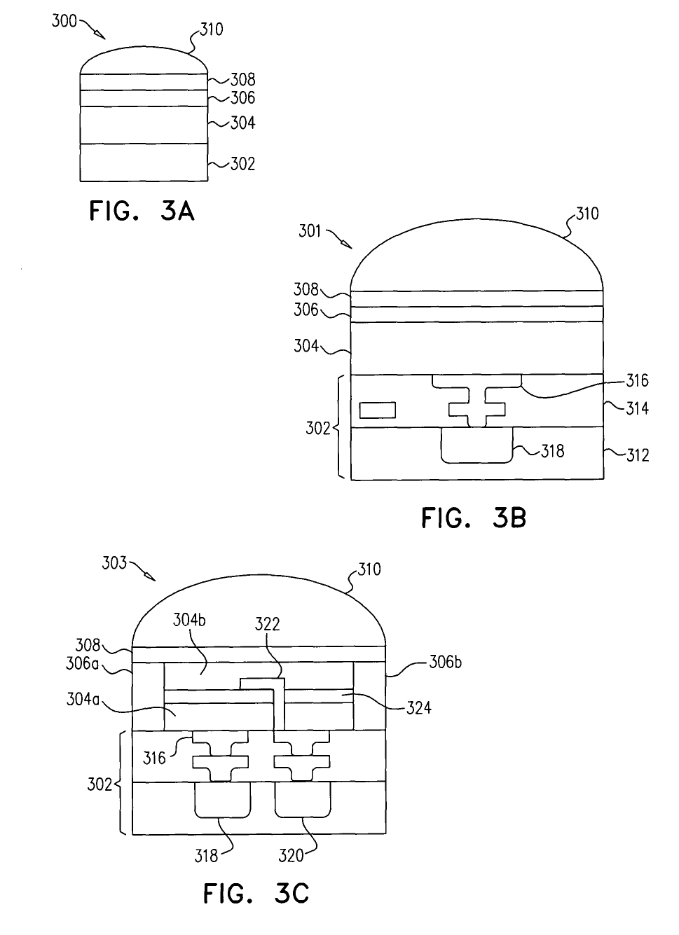

FIG. 3A is a schematic cross-sectional side view of an example pixel 300, which may be used in the image sensors described herein (such as pixel array 202 of image sensor 200 described above in relation to FIG. 2). Pixel 300 may comprise a pixel circuitry layer 302 and a photosensitive medium, in the form of a photosensitive material layer 304, which converts incident photons into charge carriers (electrons and holes) overlying pixel circuitry layer 302. Pixel circuitry layer 302 includes pixel circuits for applying control signals to and collecting charge and reading out charge collected from photosensitive material layer 304.

Photosensitive material layer 304 may be configured to absorb photons and generate one or more electron-hole pairs in response to photon absorption. In some instances, photosensitive material layer 304 may include one or more films formed from quantum dots, such as those described in the above-mentioned U.S. Pat. No. 7,923,801. The materials of photosensitive material layer 304 may be tuned to change the absorption profile of photosensitive material layer 304, whereby the image sensor may be configured to absorb light of certain wavelengths (or range of wavelengths) as desired. It should be appreciated that while discussed and typically shown as a single layer, photosensitive material layer 304 may be made from a plurality of sub-layers. For example, the photosensitive material layer may comprise a plurality of distinct sub-layers of different photosensitive material layers.

Additionally or alternatively, photosensitive material layer 304 may include one or more sub-layers that perform additional functions, such as providing chemical stability, adhesion or other interface properties between photosensitive material layer 304 and pixel circuitry layer 302, or for facilitate charge transfer across the photosensitive material layer 304. It should be appreciated that sub-layers of photosensitive material layer 304 may optionally be patterned such that different portions of the pixel circuitry may interface with different materials of the photosensitive material layer 304. For the purposes of discussion in this application, photosensitive material layer 304 will be discussed as a single layer, although it should be appreciated that a single layer or a plurality of different sub-layers may be selected based on the desired makeup and performance of the image sensor.

To the extent that the image sensors described here comprise a plurality of pixels, in some instances a portion of photosensitive material layer 304 may laterally span multiple pixels of the image sensor. Additionally or alternatively, photosensitive material layer 304 may be patterned such that different segments of photosensitive material layer 304 may overlie different pixels (such as an embodiment in which each pixel has its own individual segment of photosensitive material layer 304). As mentioned above, photosensitive material layer 304 may be in a different plane from pixel circuitry layer 302, such as above or below the readout circuitry relative to light incident thereon. That is, the light may contact photosensitive material layer 304 without passing through a plane (generally parallel to a surface of the photosensitive material layer) in which the readout circuitry resides.

In some instances, it may be desirable for photosensitive material layer 304 to comprise one or more direct bandgap semiconductor materials while pixel circuitry layer 302 comprises an indirect bandgap semiconductor. Examples of direct bandgap materials include indium arsenide and gallium arsenide, among others. The bandgap of a material is direct if a momentum of holes and electrons in a conduction band is the same as a momentum of holes and electrons in a valence band. Otherwise, the bandgap is an indirect bandgap. In embodiments in which pixel circuitry layer 302 includes an indirect bandgap semiconductor and photosensitive material layer 304 includes a direct bandgap semiconductor, photosensitive material layer 304 may promote light absorption and/or reduce pixel-to-pixel cross-talk, while pixel circuitry layer 302 may facilitate storage of charge while reducing residual charge trapping.

Pixel 300 typically comprises at least two electrodes for applying a bias to at least a portion of photosensitive material layer 304. In some instances, these electrodes may comprise laterally-spaced electrodes on a common side of the photosensitive material layer 304. In other variations, two electrodes are on opposite sides of the photosensitive material layer 304. In these variations, a top electrode 306 is overlaid on photosensitive material layer 304. The pixel circuits in pixel circuitry layer 302 collect the charge carriers from photosensitive material layer 304 while top electrode 306 applies an appropriate bias potential across layer 304. The pixel circuits output a signal corresponding to the charge carriers collected in each image readout frame.

In embodiments that include top electrode 306, the image sensor is positioned within an imaging device such that oncoming light passes through top electrode 306 before reaching photosensitive material layer 304. Accordingly, it may be desirable for top electrode 306 to be formed from a conductive material that is at least partially transparent to the wavelengths of light that the image sensor is configured to detect. For example, top electrode 306 may comprise a transparent conductive oxide. In some instances, electrode 306 is configured as a common electrode, which spans multiple pixels of an image sensor. Additionally or alternatively, electrode 306 optionally may be patterned into individual electrodes such that different pixels have different top electrodes. For example, there may be a single top electrode that addresses every pixel of the image sensor, one top electrode per pixel, or a plurality of top electrodes wherein at least one top electrode address multiple pixels.

The bias potential applied to top electrode 306 may be switched on and off at specified times during each readout frame to define a shutter period, during which the pixels integrate photocharge. In some embodiments, control circuitry (such as control circuitry 208) drives top electrode 306 to apply the bias potential to photosensitive material 304 during multiple distinct shutter periods within one or more readout frames. These embodiments enable the control circuitry to acquire multiple time slices within each such frame, as described further hereinbelow.

In some instances pixel 300 may further comprise one or more filters 308 overlaying the photosensitive material layer 304. In some instances, one or more filters may be common to the pixel array, which may be equivalent to moving filter 106 of FIG. 1 into image sensor 102. Additionally or alternatively, one or more of filters 308 may be used to provide different filtering between different pixels or pixel regions of the pixel array. For example, filter 308 may be part of a color filter array, such as a Bayer filter, CMY filter, or the like.

Additionally, in some variations, pixel 300 may comprise a microlens overlying at least a portion of the pixel. The microlens may aid in focusing light onto photosensitive material layer 304.

FIG. 3B is a schematic cross-sectional side view of a variation of a pixel 301, which shows a portion of pixel circuitry layer 302 in greater detail. Common components to those described in FIG. 3A are labeled with the same numbers as in FIG. 3A. Pixel circuitry layer 302 can include a semiconductor substrate layer 312 and/or one or more metal layers (collectively referred to herein as metal stack 314) which collectively perform biasing, readout, and resetting operations of the image sensor. Semiconductor substrate layer 312 may include a semiconductor material or combination of materials, such as silicon, germanium, indium, arsenic, aluminum, boron, gallium, nitrogen, phosphorus, doped versions thereof. In one or more embodiments, semiconductor layer 312 includes an indirect-bandgap semiconductor (e.g., silicon, germanium, aluminum-antimonide, or the like). In instances in which the pixel circuitry comprises a metal stack 314, the metal layers may be patterned to form contacts, vias, or other conductive pathways which may be insulated by a dielectric such as SiO2. It should be appreciated that metal stack 314 and the associated interconnect circuitry may be formed using traditional complementary metal-oxide semiconductor (CMOS) processes.

As shown in FIG. 3B, metal stack 314 may comprise a pixel electrode 316, which along with a second electrode (e.g., a laterally-spaced electrode or top electrode 306) may provide a bias to the photosensitive layer during one or more operations of the image sensor. The metal layers may further form a via between metal stack 314 and semiconductor substrate layer 312 to provide a connection therebetween.

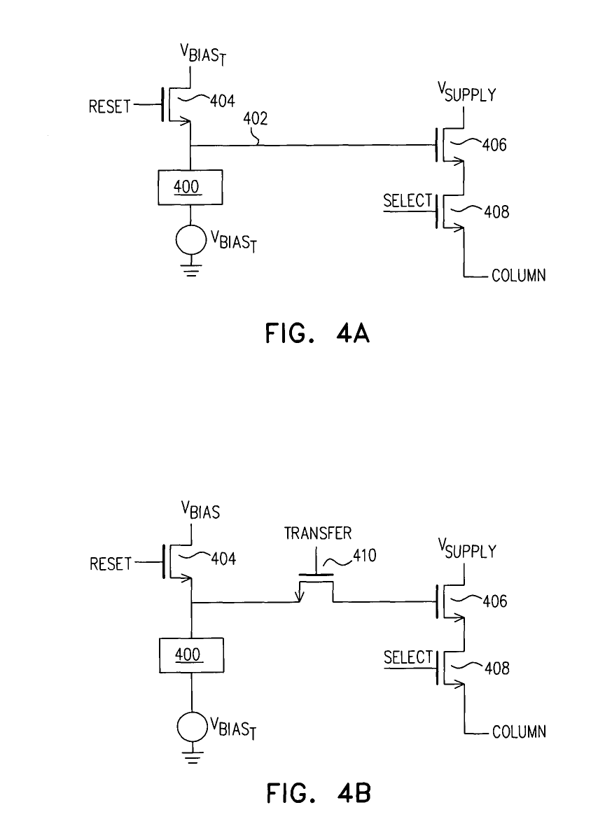

To facilitate the collection and transfer of charge within the pixel, one or more transistors, diodes, and photodiodes may formed in or on a semiconductor substrate layer 312, for example, and are suitably connected with portions of metal stack 314 to create a light-sensitive pixel and a circuit for collecting and reading out charge from the pixel. Pixel circuitry layer 302 may facilitate maintaining stored charges, such as those collected from the photosensitive layer. For example, semiconductor substrate layer 312 may comprise a sense node 318, which may be used to temporarily store charges collected from the photosensitive layer. Metal stack 314 may comprise first interconnect circuitry that provides a path from pixel electrode 316 to sense node 318. While metal stack 314 is shown in FIG. 3B as providing a direct pathway between pixel electrode 316 and sense node 318 without intervening circuitry, it should be appreciated that in other instances (such as in circuitry described below with reference to FIG. 4B), one or more intervening circuit elements may be positioned between pixel electrode 316 and sense node 318.

FIG. 3C shows another variation of a pixel 303, which is similar to pixel 301 of FIG. 3B (with common components from FIG. 3B labeled with the same numbers), except that pixel 303 comprises a plurality of separate photosensitive layers, which may each provide electrical signals. As shown in FIG. 3C, pixel 303 may comprise a first photosensitive layer 304a and a second photosensitive layer 304b overlying first photosensitive layer 304a. An insulating layer 324 may separate first photosensitive layer 304a from second photosensitive layer 304b, such that each photosensitive layer may be independently biased. Accordingly, pixel 303 may comprise a plurality of electrodes to provide a respective bias to each of first photosensitive layer 304a and second photosensitive layer 304b. For example, in the variation shown in FIG. 3C, pixel 303 may comprise a first electrode 316 connected to first photosensitive layer 304a, a second electrode 322 connected to second photosensitive layer 304b, and one or more common electrodes (shown as two electrodes 306a and 306b, although these electrodes may be combined into a single electrode) connected to both the first and second photosensitive layers around at least a portion of the periphery of pixel 303.

To reach second photosensitive layer 304b, at least a portion of second electrode 322 may pass through a portion of first photosensitive layer 304a and insulating layer 324. This portion of second electrode 322 may be insulated to insulate the second electrode from first photosensitive layer 304a. A first bias may be applied to first photosensitive layer 304a via first electrode 316 and the common electrodes, and a second bias may be applied to second photosensitive layer 304b via second electrode 322 and the common electrodes. While shown in FIG. 3C as sharing one or more common electrodes, the first and second photosensitive layers need not share any electrodes. For example, the first and second photosensitive layers (and corresponding electrodes) may be configured in any suitable fashion, such as those described in U.S. Patent Application Publication 2016/0155882, the contents of which are incorporated herein by reference in their entirety.

Each photosensitive layer may be connected to the pixel circuitry in such a way that the photosensitive layers may be independently biased, read out, and/or reset. Having different photosensitive layers may allow the pixel to independently read out different wavelengths (or wavelength bands) and/or read out information with different levels of sensitivity. For example, first photosensitive layer 304a may be connected to a first sense node 318 while second photosensitive layer 304b may be connected to a second sense node 320, which in some instances may be separately read out to provide separate electrical signals representative of the light collected by the first and second photosensitive layers respectively.

FIGS. 4A and 4B show example pixel circuitry which may be used to bias, read out, and reset individual pixels. While FIG. 4A shows a three transistor (3T) embodiment and FIG. 4B shows a four transistor (4T) embodiment, it should be appreciated that these are just exemplary circuits and any suitable pixel circuitry can be used to perform these operations. For example, suitable pixel circuitry embodiments are described in US Patent Application Publications 2017/0264836, 2017/0208273, and 2016/0037114, the contents of each of which are incorporated herein by reference in their entirety.

Turning to FIG. 4A, the pixel circuitry may be configured to apply a first bias potential V_{BiasT}, which may be applied to a photosensitive layer 400 (e.g., via a first electrode such as a top electrode as discussed above). Photosensitive layer 400 may also be connected to a sense node 402 (e.g., via a pixel electrode such as discussed above). Sense node 402 may be connected to a second bias potential V_{BiasB} via a reset switch 404 (which is controlled by a reset signal RESET). Reset switch 404 may be used to reset sense node 402 at various points during operation of the image sensor. The pixel circuit of FIG. 4B is identical to that of FIG. 4A, except that in FIG. 4B the pixel circuit includes a transfer switch 410 positioned between photosensitive layer 400 and the sense node. The transfer switch may be used to facilitate transfer of charge between photosensitive layer 400 and the pixel output.

Sense node 402 may further be connected to an input of a source follower switch 406, which may be used to measure changes in sense node 402. Source follower switch 406 may have its drain connected to a voltage source VSUPPLY and its source connected to a common node with the drain of a select switch 408 (controlled by a select signal SELECT). The source of select switch 408 is in turn connected to an output bus COLUMN. When select switch 408 is turned on, changes in sense node 402 detected by follower switch 406 will be passed via select switch 408 to the bus for further processing.

The image sensors described here may be configured to read out images using rolling shutter or global shutter techniques. For example, to perform a rolling shutter readout using the pixel circuitry of FIG. 4A, a first reset may be performed to reset the sense node prior to integration. Reset switch 404 may be opened to reset sense node 402 to the second potential V_{BiasB}. Closing reset switch 404 may initiate an integration period, during which one or more measurements may be taken to measure the potential of sense node 402 (which may vary as the photosensitive layer absorbs light). A second reset may end integration. The period between the second reset and the first reset of a subsequent frame may depend on the frame readout rate.

Similarly, the pixel circuitry of FIG. 4A may adjust the first potential V_{BiasT} to achieve a global shutter operation. In these instances the first potential V_{BiasT} may be driven at a first level during integration and at a second level outside of integration. The second level of the first potential V_{BiasT} may be selected such that charges generated in the photosensitive material are not collected by the pixel electrode. A first reset may be used to reset the pixel electrode and sense node to the second potential V_{BiasB} at the start of integration. During integration (which may occur simultaneously across multiple rows of the image sensor), the sense node potential may change based on the amount of light absorbed by photosensitive layer 400. After integration, the first potential V_{BiasT} may be returned to the second level, and the charge on the sense node may be read out. A second reset may again reset the sense node to the second potential, and a second reading of the sense node may be read out. The multiple readings can be used, for example, in a correlated double sampling (CDS) operation.

### Acquisition of Multiple Time Slices in a Single Image Frame

The tracking of objects in space and time is of interest in a number of applications. For example, user interfaces benefit from the capability to recognize certain gestures. An example is a left-right swipe, which could signal turning forward to the next page of a book; a right-left swipe, which could signify turning back; and up-to-down and down-to-up swipes, signaling scrolling directions.

In applications such as these, it is important to ascertain that such gestures are being implemented and to distinguish their directions. Such gesture recognition is of interest on multiple timescales. One unit of time common to most image sensors and cameras is the frame time, i.e., the time it takes to read out one image or frame.

In some cases, a gesture may be substantially completed within a given frame time (such as within a 1/15, 1/30, or 1/60 second frame duration). In other cases, the gesture may be completed over longer time periods, in which case acquisition and recognition can occur on a multi-frame timescale. In some applications, information on both of these timescales may be of interest: For example, fine-grained information may be obtained on the within-frame timescale, while coarser information may be obtained on the multi-frame timescale.

Implementations of gesture recognition can take advantage of the acquisition of multiple independent frames, each of which is acquired, saved in a frame memory (on or off a given integrated circuit), and processed. In the present embodiments, it is of interest to capture the information related to a gesture or other motion within a single image or frame. In this case, the image data acquired within this single frame is processed and stored for the purpose of identifying moving objects and analyzing the distances and velocity by which they have moved.

The embodiments that are described hereinbelow enable capture of this sort of information using the global shutter (GS) functionality of film-based image sensors. In particular, image sensors based on quantum films are capable of global shutter operation without additional transistors or storage nodes. Photon collection of the pixels can be turned on and off by changing the bias across the film, as explained above, and in particular can be turned on during multiple distinct shutter periods within each of the readout frames.

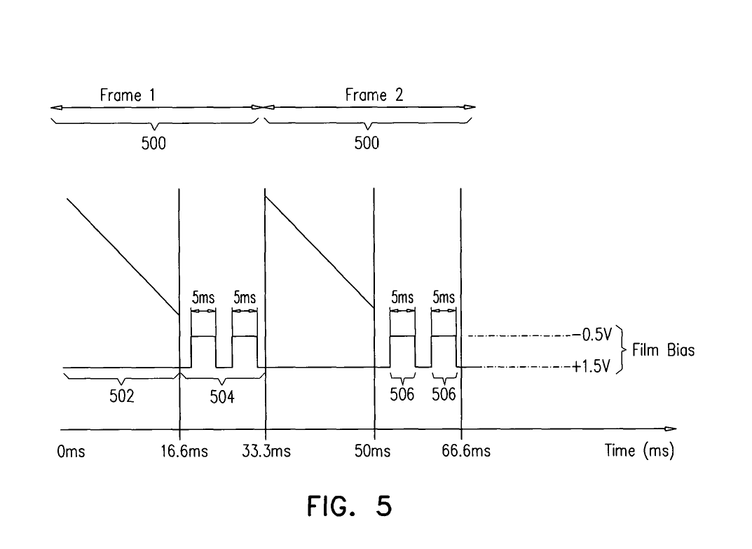

FIG. 5 is a signal timing diagram that schematically illustrates the operation of an image sensor with a global shutter, in accordance with an embodiment of the invention. The signals in the figure correspond to a periodic sequence of readout frames 500, which include alternating readout periods 502 and blanking periods 504 (also referred to as vertical blanking intervals). Each blanking period includes multiple distinct shutter periods 506. In the pictured example, each frame 500 is 33.3 ms, in accordance with standard video timing of 30 frames/sec, but alternatively other frame rates and frame durations, greater than or less than those shown in this example, may be used. Similarly, although readout periods 502 and blanking periods 504 are shown as being of equal duration within each frame, the proportion between these periods may vary depending on device capabilities and application requirements.

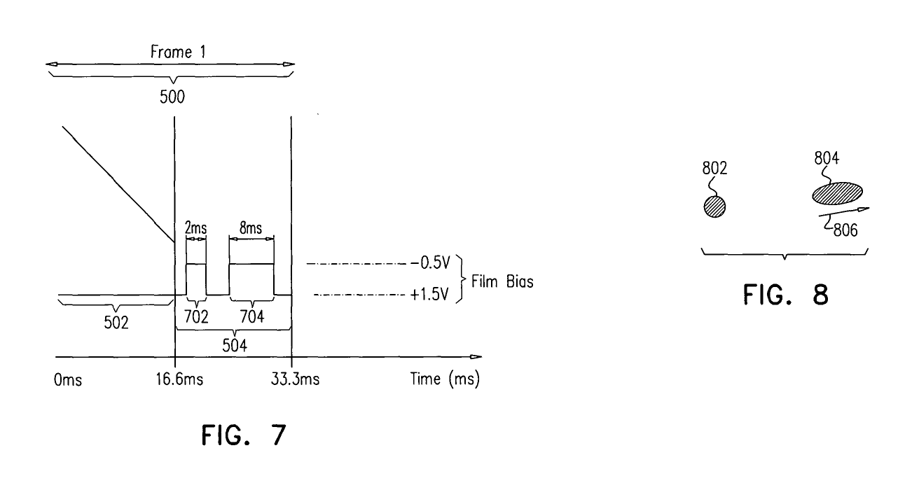

Furthermore, although two shutter periods 506 of 5 ms duration are shown in each blanking period 504 in FIG. 5, the shutter periods may be longer or shorter, and there may be more than two shutter periods in each blanking period, up to a maximum determined by the lighting conditions and sensitivity of the photosensitive medium. (Short shutter periods under low light conditions may give poor signal/noise ratio in the signals output by the pixels.) In the example shown in FIG. 5, shutter periods 506 are of equal durations. In alternative embodiments (as shown in FIG. 7, for example), the shutter periods may have different respective durations.

The film bias, marked at the right side of the figure, corresponds to the potential applied by the common electrode across the photosensitive medium, such as a quantum film, in the pixels of an image sensing array. Referring to FIGS. 3B and 4A, for example, the film bias is the potential difference between electrodes 306 and 316 and is switched between ON and OFF states by operation of reset switch 404. The film bias creates an electric field that either facilitates or negates movement of photocharges generated in the photosensitive medium (such as layer 304), depending on the voltage applied. Typically, the film bias has separate ON and OFF voltage, whose levels depend on the composition of the photosensitive material. For example, the majority carrier of the photocharges can be either electrons or holes, depending on the device structure. In the pictured example, a voltage between −0.2V to −1V, for instance −0.5V, is chosen as the ON voltage for the film bias when the majority carrier is electrons, and an OFF voltage of +1.5V can be chosen for the same case. The ON voltage is applied to enable collection of photocharge during shutter periods 506, and the voltage is switched to the OFF value during the remainder of each frame 500.

Readout period 502 represents the time required for all the rows of the image sensor to be read out, typically in rolling order, as depicted by the slanted line in FIG. 5. The starting point of the line denotes the readout of the first row in the pixel array, and the ending point denotes the time at which the last row is read out. The rolling readout time can vary depending upon the application, the number of rows and columns to be read out, and the frame rate desired. Because the film bias is turned OFF during readout period 502, there is no photocharge generation during the rolling readout period.

Blanking period 504, is the time in each frame 500 after all the rows have been read out and before the next frame readout begins. As explained above, the film bias is switched to the ON voltage during one or more variable shutter periods 506 during blanking period 504 so that the pixels in the array collect the photocharge generated by the photosensitive medium. Shutter periods 506 are also referred to as the integration times. Following the shutter periods, the film bias is set back to the OFF voltage, so that photocharge generation is stopped, and the pixels in all rows can then be read out as the next frame or image.

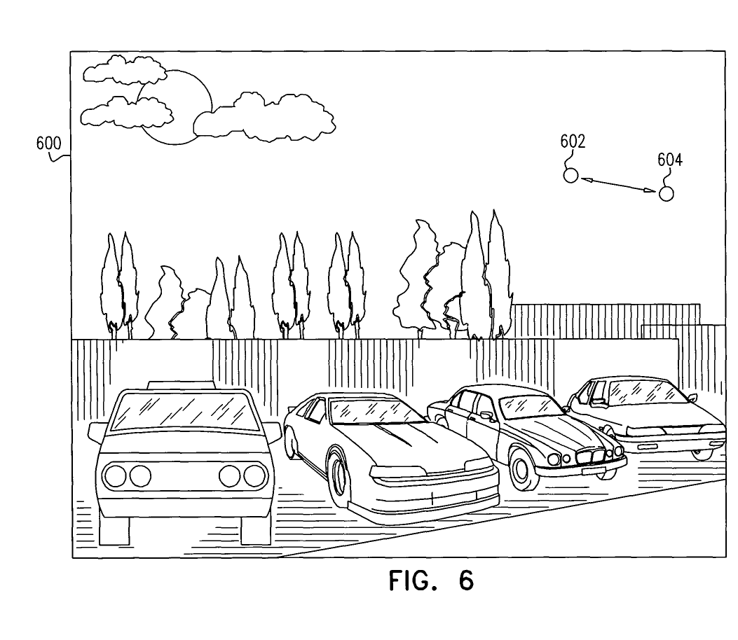

FIG. 6 is a schematic representation of an image 600 captured by an image sensor using two shutter periods in a readout frame, in accordance with an embodiment of the invention. Image 600 was captured by a film-based image sensor, such as image sensor 200 (FIG. 2), operating in accordance with the sort of signal timing that is illustrated in FIG. 5. A ball was thrown across the scene shown in image 600, with the result that the image contains a ball in two different positions 602 and 604: a first position 602 captured during the first shutter period 506 in the frame, and a second position 604 captured during the second shutter period.

As illustrated by FIG. 6, the use of multiple shutter periods thus allows for capture of a moving object at multiple positions in its motion. Control circuitry, such as circuitry 208 or an external image processor, can process image 600 in order to identify a moving object in the image based on its appearance in multiple segments. The control circuitry can estimate the velocity of the moving object based on the distance between the different locations of the moving object that it detects, such as positions 602 and 604, and the known timing of shutter periods 506. In this case, only the magnitude of the velocity can be extracted, however, and not the direction, since it is not known which of positions 602 and 604 was captured during the first shutter period and which was captured during the second.

A similar approach can be applied in other motion-sensing applications, such as detecting and analyzing rapid hand gestures. As another example of the possible use of this sort of multi-exposure scheme, in a structured light application, the illuminator can be moved during each frame, and the spots captured in multiple shutter periods can then be combined to create a more accurate depth map in cases in which the number of spots created by the illuminator is limited.

FIG. 7 is a signal timing diagram that schematically illustrates the operation of an image sensor with a global shutter, in accordance with another embodiment of the invention. The timing of the signals in FIG. 7 is similar to that shown in FIG. 5, and similar elements are therefore labeled with the same reference numbers. In FIG. 7, however, shutter periods 702 and 704 have different, respective durations, for example, 2 ms for shutter period 702 and 8 ms for shutter period 704.

Varied shutter periods of this sort can be used for slower-moving objects, for which the difference in exposures does not dramatically change the perceived shape of the object, and the illumination does not change dramatically in the timescales of the multiple exposures. Additionally or alternatively, the control circuitry can use the varying shutter periods in extracting directional information with respect to moving objects. When the signal timing shown in FIG. 7 is used, for example, the image of a moving object that is captured during shutter period 704 will be brighter than that captured during shutter period 702. The control circuitry will thus be able to identify the order in which the images of the object were created and hence the direction in which the object was moving. Further additionally or alternatively, the control circuitry can analyze changes in the shape of the images of the object to infer the direction of motion.

FIG. 8 is a schematic representation of images 802 and 804 of an object, such as the ball shown in FIG. 6, captured by an image sensor using two unequal shutter periods in a readout frame, in accordance with an embodiment of the invention. In this embodiment, image 802 of the ball is captured during shutter period 702, and another image 804 of the ball is captured during shutter period 704. The longer exposure of shutter period 704 causes the shape of the ball to be distorted in image 804. By comparing the shapes of images 802 and 804, the control circuitry is able to associate each image with the corresponding shutter period, and to infer that the ball was moving toward the right, as indicated by an arrow 806.

In some embodiments, the techniques described above for creating multiple shutter periods during a given frame can be used in synchronization with a pulsed illumination source, which illuminates a scene while an image of the scene is captured by the image sensor. The illumination source, such as an LED or laser, is typically pulsed during the shutter periods of the image sensor. The illuminator power can be varied, so that the image sensor is exposed to a different intensity level in each shutter period, and the difference in image brightness can then be used in determining both the magnitude and the direction of the velocity of motion. In this case, the shutter periods can be identical and short in order to prevent motion smear and object distortion.

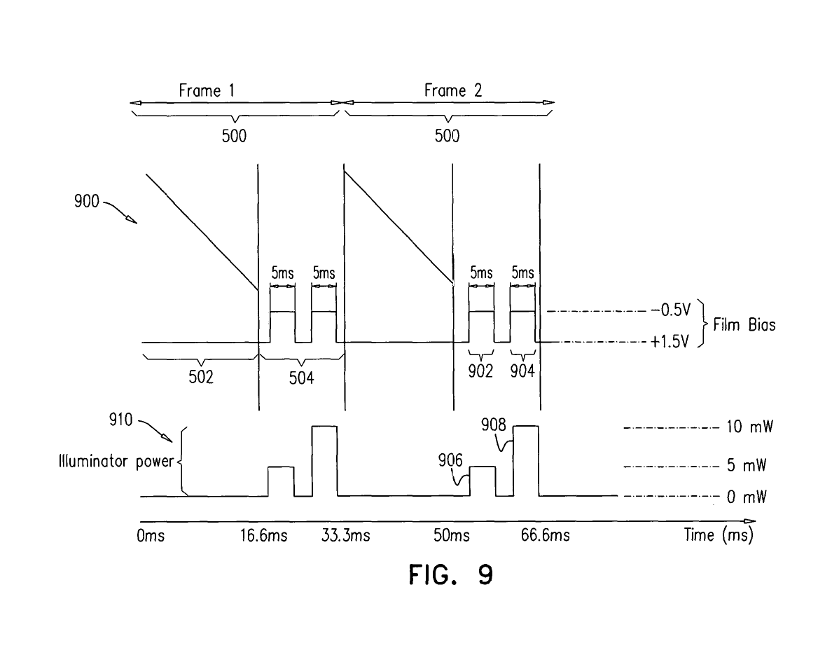

FIG. 9 is a signal timing diagram that schematically illustrates the operation of an image sensor with a global shutter in synchronization with a pulsed illumination source, in accordance with this sort of embodiment of the invention. The timing of the signals applied to the image sensor in FIG. 9, as presented in an upper plot 900, is similar to that shown in FIG. 5, and similar elements are therefore labeled with the same reference numbers. In FIG. 9, however, shutter periods 902 and 904 are synchronized with illumination pulses 906 and 908, as shown in a lower plot 910. In the pictured example, pulse 908 has twice the power of pulse 906, so that the images of moving objects captured during shutter period 904 will be roughly twice as bright as the images of the same objects captured during shutter period 902.

Alternatively, other sorts of synchronized pulse patterns, with various durations and power levels, may be used. For example, it is possible to simultaneously modulate the power and pulse durations in order to reduce illuminator power. An optimal tradeoff between the pulse duration and power modulation can be determined based on the object distance and acceptable distortion.

In some embodiments, as illustrated in FIG. 3C, for example, a film-based image sensor may comprise multiple photosensitive layers, which convert incident photons in different, respective wavelength bands into charge carriers. For example, one wavelength band may be a visible wavelength band, while the other is an infrared wavelength band. Such multi-wavelength image sensors can also have multiple bias electrodes, which are capable of separately biasing each of the photosensitive layers. Some embodiments of the present invention take advantage of this multi-layer structure in driving the bias electrodes to apply the bias potential to only one of the photosensitive layers during a first shutter period and to only another photosensitive layer during another, second shutter period.

With this approach, motion and velocity vectors can be estimated by staggering the exposures of the photosensitive layers in the different wavelength bands. Specifically, although the bias controls for the different layers are separated, the same pixel readout timing is maintained for both layers. Thus, the shutter periods can be staggered between the layers, making it possible to determine the motion and velocity vectors in a single frame readout of the multi-wavelength-band information.

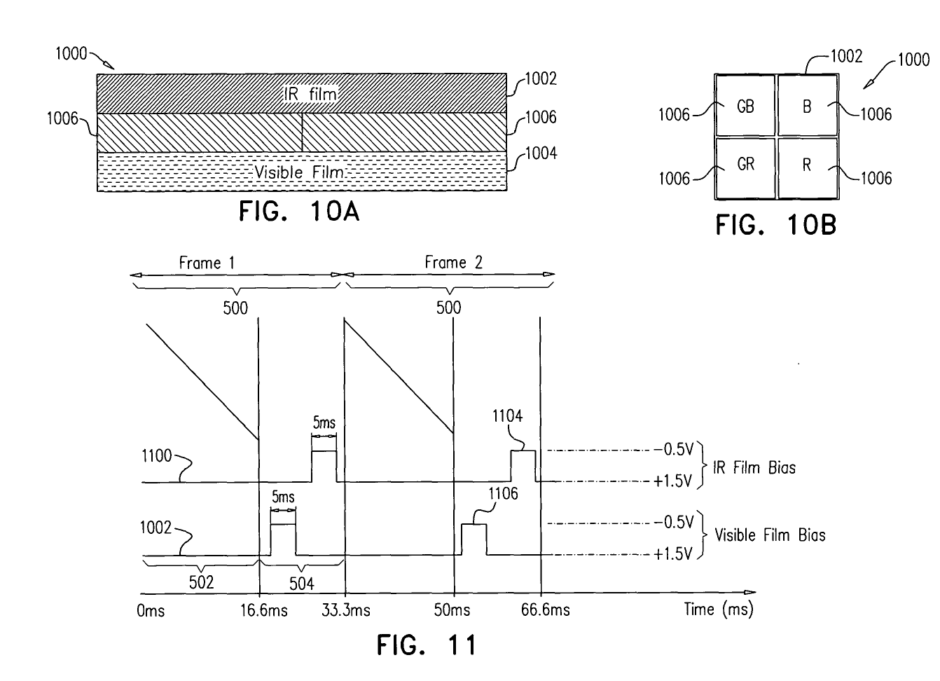

FIGS. 10A and 10B are schematic sectional and top views, respectively, of a group 1000 of pixels in an image sensor, which can be used in the sort of multi-exposure scheme that is described above, in accordance with an embodiment of the invention. An infrared-sensitive quantum film 1002 is overlaid above a quantum film 1004 that is sensitive to visible light, which is in turn overlaid on the pixel circuits (not shown in this figure) of the pixels in group 1000. Optionally, an array of color filters 1006 is overlaid on the pixel array, for example in a Bayer pattern, as is known in the art, so that the pixels in group 1000 sense different colors of the incident visible light. When the appropriate bias is applied across film 1002, the pixels in group 1000 will sense incident infrared light; whereas applying the proper bias across film 1004 will cause the pixels to sense incident visible light.

FIG. 11 is a signal timing diagram that schematically illustrates the operation of the image sensor of FIGS. 10A/B with separate global shutters for films 1002 and 1004, in accordance with another embodiment of the invention. Frames 500, readout intervals 502, and blanking intervals 504 are defined as in the preceding embodiments. An upper trace 1100 shows the bias voltage applied across film 1002, in order to collect photocharge due to incident infrared light, while a lower trace 1102 shows the bias voltage applied across film 1004, for collecting photocharge due to incident visible light. Bias pulses 1104 and 1106 are applied across films 1002 and 1004, respectively, during different, respective shutter periods.

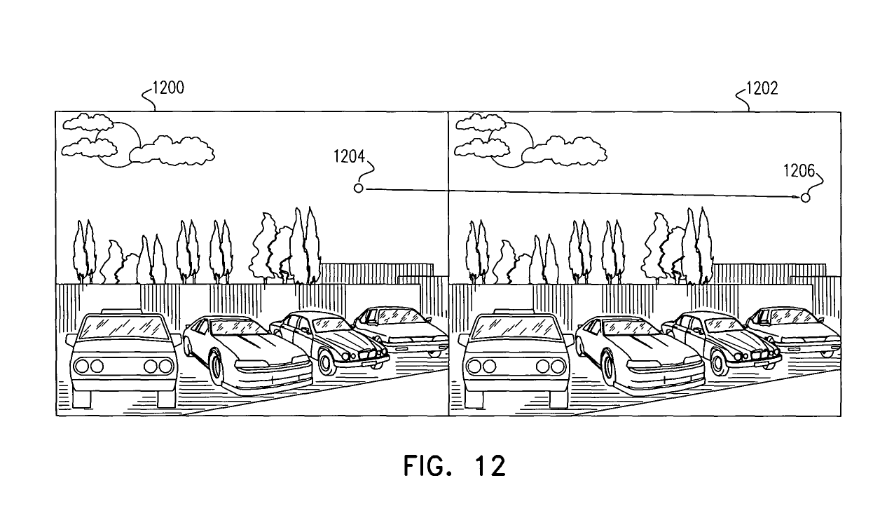

FIG. 12 is a schematic representation of images 1200 and 1202 captured by the image sensor of FIGS. 10A/B upon application of the signals shown in FIG. 11, in accordance with an embodiment of the invention. Image 1200 is captured in visible light during a first shutter period, defined by pulse 1106, and image 1202 is captured in infrared light during a second, subsequent shutter period, defined by pulse 1104. An image 1204 of an object, such as a ball, is captured during the first shutter period, and another image 1206 of the same ball is captured during the second shutter period. As the temporal relation between the shutter periods for the two wavelength bands is known, the motion and velocity vectors of the ball can be found unequivocally by comparing images 1200 and 1202.

FIG. 13 is a schematic top view of an image sensor 1300, in which different photosensitive layers are overlaid on different, respective sets 1302, 1304 of pixel circuits, in accordance with another embodiment of the invention. Due to the different photosensitive layers, the pixels in sets 1302 and 1304 will be sensitive to different wavelength bands, at wavelengths λ₁ and λ₂ (which may be visible and infrared wavelength bands, for example, or any other suitable wavelengths). Sets 1302 and 1304 may be configured as separate, adjoining arrays, as shown in FIG. 13, or they may be interleaved within a single array. As in the preceding embodiments, the photosensitive layers overlying sets 1302 and 1304 are biased ON in different, respective shutter periods, thus enabling the motion and velocity vectors of objects to be inferred from a single image frame in the manner described above.

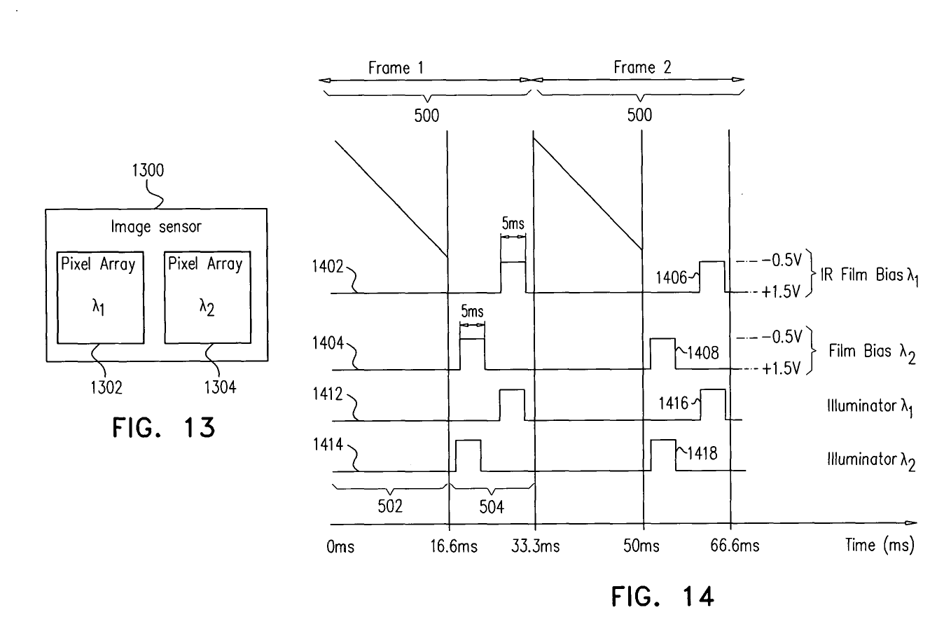

FIG. 14 is a signal timing diagram that schematically illustrates the operation of image sensor 1300 with global shutters synchronized in both time and wavelength with a pulsed illumination source, in accordance with another embodiment of the invention. This scheme makes it possible to detect motion with high sensitivity, particularly if sets 1302 and 1304 of pixels are configured for narrowband sensitivity, for example by overlaying the respective photosensitive layers with suitable optical bandpass filters. These filters are matched to the pair of corresponding wavelengths λ₁ and λ₂ that are emitted by the illumination source (for example by alternately pulsing a pair of LEDs or lasers to emit radiation at the desired wavelengths).

Traces 1402 and 1404 in FIG. 14 represent the bias voltages applied across the photosensitive layers of sets 1302 and 1304 of pixels for wavelengths λ₁ and λ₂, respectively. The two sets of pixel have shutter periods defined by respective pulses 1406 and 1408. These shutter pulses are synchronized with emission pulses 1416 and 1418 of the corresponding illumination sources, at wavelengths λ₁ and λ₂, whose drive voltages are illustrated by traces 1412 and 1414.

### Acquisition of Multiple Time Slices Across Multiple Frames

In other embodiments, an image sensor can be designed such that application of a bright light temporarily imprints the sensor with an image. The imprint can stay for a controllable amount of time, ranging from 0-10 frame lengths. The image sensor can be designed so that the imprint only happens when the photosensitive material, such as a quantum film, in the pixels is biased in a particular direction and magnitude, so as to drive charge into a region of the material where it becomes trapped. Because the charge only becomes trapped when the photosensitive material is biased in a certain way, by carefully controlling the bias timing of the device, an image can be temporarily imprinted in the sensor at a particular location, corresponding to the coincidence of a bright light illuminating pixels that are biased to drive charge toward the direction where they will become trapped.

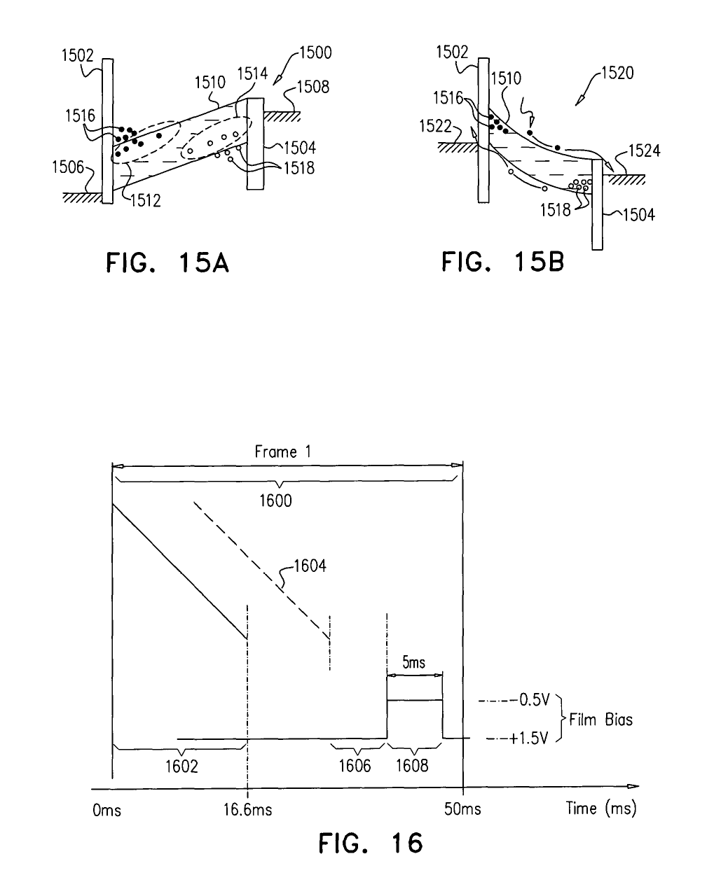

FIGS. 15A and 15B are electrical band diagrams showing potential distributions 1500 and 1520, respectively, within a photosensitive medium under different bias voltage conditions, in accordance with an embodiment of the invention. In FIG. 15A, the applied bias between layers 1502 and 1504, represented by respective potential levels 1506 and 1508, drives holes 1518 toward layer 1504. Due to the wide band gap of layer 1504 (which may comprise TiO₂, for example), hole extraction through layer 1504 is very slow such that holes pile up and fill empty trap states 1518 in a semiconducting layer band 1510. Electrons 1516 may likewise be trapped in trap states 1512.

In FIG. 15B the bias voltage, represented by potential levels 1522 and 1524, has been reset so that electrons 1516 will move toward layer 1504. In normal device operation, the bias across the semiconducting layer during this phase is very small, so that the photocurrent collection is near zero and the pixel is effectively off, thus creating the global shutter operation. In the scenario described below, however, the charge that was trapped in the previous frame creates a built-in field. In such embodiments, the field in the semiconductor layer has been increased so that the efficiency of photocurrent collection is now greater than zero, meaning that the global shutter has been temporarily disabled.

In these embodiments, once charge is trapped, it can stay trapped for a period of time ranging from milliseconds to several seconds. The trapped charge can alter the field applied across the photosensitive medium, such that where charge is trapped, the global shutter capability of the pixel in question is temporarily disabled. When the pixels are subsequently illuminated with ambient light, they will produce a signal only where charge is trapped. In the other parts of the image sensor where no charge (or less charge) was trapped, the global shutter is still enabled and the device does not record any signal, even though there is light incident upon it. The result of this behavior is to create one or more “imprints” of a bright object on the image sensor. The imprints are spaced apart by a number of pixels equal to the product of the frame duration by the object velocity (in pixels), and get dimmer as they get farther from the original object. By using single-frame image processing to locate all the imprints in a single frame, it is possible to determine the velocity of motion from the spacing of the imprints, as well as the direction of motion, by the direction of increasing imprint intensity.

In some embodiments, the image sensor can be designed so that the imprint is created only by parts of the scene that are much brighter than the background. This feature can be implemented because the creation of the imprint by trapping charge against the hole-blocking layer of the pixels can occur only when the photosensitive medium is biased to drive holes in that direction. The bias can be chosen so that holes are driven toward the hole-blocking layer only when a light is sufficiently bright to drive the sense node voltage very low during the main integration period. Increasing the duration of the main integration period causes the sense node voltage to go lower for a given light intensity, thus making it easier for light of a given intensity to cause holes to be driven toward the hole-blocking layer and create an imprint. Alternatively, the main integration time can be decreased so that only very bright lights drive the sense node voltage low enough for holes to be driven toward the hole-blocking layer and create an imprint. The main integration time can thus be used to adjust how bright a light must be before it creates an imprint. In embodiments in which there are many bright objects in a scene, this tuning can be used so that only the brightest moving image creates an imprint, while the static background, which is slightly less bright, does not create an imprint.

These techniques can be used to acquire gesture information that spans multiple frames. For example, if the object is more slowly-moving, its image may traverse the imaged scene over multiple tenths of a second.

In some cases, it can be desirable for objects, especially those lying in a high range of intensities (e.g., very bright objects, such as those actively illuminated to the point of saturation), to provide signals within the acquired image frame that indicate their locations over multiple frame intervals. In some embodiments of this sort, an optically-sensitive layer acquires an image of a bright object during a first period, and as a result rapidly integrates down the voltage on a pixel electrode. During a second period, the optically-sensitive layer acquires a large signal selectively only in cases in which the pixel electrode is now lower than a certain bias level. As a result, the region that was illuminated brightly in the first period provides an imprint, during an ensuing frame period, of the illumination position during the first period. The amplitude of the imprint may be controlled, for example, by providing a reset having a specific timing relative to the shutter transition.

FIG. 16 is a signal timing diagram that schematically illustrates the operation of an image sensor in capturing imprints over multiple frames, in accordance with an embodiment of the invention. A frame 1600 in this case includes a rolling readout period 1602, as in the preceding embodiments, followed by a second reset 1604. Conclusion of the second reset defines an imprint integration time 1606. Subsequently, the bias across the photosensitive layer (shown as the film bias) is switched on during a shutter period 1608, as described above.

In this embodiment, the magnitude of the imprint signal can also be tuned by adjusting imprint integration time 1606 (as opposed to the main integration time, as described above). The addition of second reset 1604 after the rolling readout and the main integration time controls how much signal is collected in the pixels in which charge is trapped. The magnitude of the imprint is determined by the amount of charge trapped in the imprinted pixels, the intensity of ambient light incident on the imprint-affected pixels after the imprint is created, and the imprint integration time.

The ability to detect the imprint can be increased by moving second reset 1604 closer in time to rolling readout period 1602, such that imprint integration time 1606 increases. This approach can be advantageous in scenes in which the moving object to be detected is of similar brightness to a static background, in enhancing detection of the imprint against the static background.

Alternatively, the imprint can be decreased in magnitude by moving second reset 1604 closer in time to the main integration period. This approach can be advantageous in scenes in which the moving object is much brighter than the static background so that it is easy to pick the imprint out, and there is a desire to limit the amount of time the imprint endures. By reducing the imprint integration time, the oldest imprints, which are also the faintest, can be reduced in intensity such that they are not detectable. In such embodiments, imprint integration time 1606 can be used to effectively control the number of imprints that appear, for example in a range between zero and ten imprints.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. Imaging apparatus, comprising:
a photosensitive medium configured to convert incident photons into charge carriers;
a common electrode, which is at least partially transparent, overlying the photosensitive medium and configured to apply a bias potential to the photosensitive medium;
an array of pixel circuits formed on a semiconductor substrate, each pixel circuit defining a respective pixel and configured to collect the charge carriers from the photosensitive medium while the common electrode applies the bias potential and to output a signal responsively to the collected charge carriers; and
control circuitry, which is configured to read out the signal from the pixel circuits in each of a periodic sequence of readout frames and to drive the common electrode to apply the bias potential to the photosensitive medium during each of a plurality of distinct shutter periods within at least one of the readout frames.

2. The apparatus according to claim 1, wherein the photosensitive medium comprises a quantum film.

3. The apparatus according to claim 1, wherein the plurality of the distinct shutter periods comprises at least a first shutter period and a second shutter period of equal, respective durations.

4. The apparatus according to claim 1, wherein the plurality of the distinct shutter periods comprises at least a first shutter period and a second shutter period of different, respective durations.

5. The apparatus according to claim 1, wherein the photosensitive medium comprises:
a first photosensitive layer, which is configured to convert the incident photons in a first wavelength band into the charge carriers; and
a second photosensitive layer, which is configured to convert the incident photons in a second wavelength band, different from the first wavelength band, into the charge carriers, and
wherein the control circuitry is configured to drive the common electrode to apply the bias potential only to the first photosensitive layer during a first shutter period and to apply the bias potential only to the second photosensitive layer during a different, second shutter period among the plurality of distinct shutter periods within the at least one of the readout frames.

6. The apparatus according to claim 5, wherein the first wavelength band is a visible wavelength band, while the second wavelength band is an infrared wavelength band.

7. The apparatus according to claim 5, wherein the first and second photosensitive layers are both overlaid on a common set of the pixel circuits, which collect the charge carriers in response to the photons that are incident during both of the first and second shutter periods.

8. The apparatus according to claim 5, wherein the first and second photosensitive layers are overlaid on different, respective first and second sets of the pixel circuits.

9. The apparatus according to claim 1, wherein the control circuitry is configured to synchronize the shutter periods with a pulsed illumination source, which illuminates a scene while an image of the scene is captured by the apparatus.

10. The apparatus according to claim 1, wherein the control circuitry is configured to process the signal in the at least one of the readout frames so as to identify, responsively to the plurality of the distinct shutter periods, a moving object in an image captured by the apparatus.

11. The apparatus according to claim 10, wherein the control circuitry is configured to estimate a velocity of the moving object responsively to a distance between different locations of the moving object that are detected respectively during the distinct shutter periods.

12. A method for imaging, comprising:
overlaying a common electrode, which is at least partially transparent, on a photosensitive medium configured to convert incident photons into charge carriers;
coupling an array of pixel circuits, each pixel circuit defining a respective pixel, to collect the charge carriers from the photosensitive medium while the common electrode applies a bias potential to the photosensitive medium and to output a signal responsively to the collected charge carriers;
reading out the signal from the pixel circuits in each of a periodic sequence of readout frames; and
driving the common electrode to apply the bias potential to the photosensitive medium during each of a plurality of distinct shutter periods within at least one of the readout frames.

13. The method according to claim 12, wherein the plurality of the distinct shutter periods comprises at least a first shutter period and a second shutter period of equal, respective durations.

14. The method according to claim 12, wherein the plurality of the distinct shutter periods comprises at least a first shutter period and a second shutter period of different, respective durations.

15. The method according to claim 12, wherein the photosensitive medium comprises first and second photosensitive layers, which convert the incident photons in respective first and second wavelength bands into the charge carriers, and
wherein driving the common electrode comprises applying the bias potential only to the first photosensitive layer during a first shutter period and only to the second photosensitive layer during a different, second shutter period among the plurality of distinct shutter periods within the at least one of the readout frames.

16. The method according to claim 15, wherein the first wavelength band is a visible wavelength band, while the second wavelength band is an infrared wavelength band.

17. The method according to claim 12, wherein driving the common electrode comprises synchronizing the shutter periods with a pulsed illumination source, which illuminates a scene while an image of the scene is captured by the array.

18. The method according to claim 12, and comprising processing the signal in the at least one of the readout frames so as to identify, responsively to the plurality of the distinct shutter periods, a moving object in an image captured by the method.

19. The method according to claim 19, wherein processing the signal comprises estimating a velocity of the moving object responsively to a distance between different locations of the moving object that are detected respectively during the distinct shutter periods.

20. Imaging apparatus, comprising:
a photosensitive medium configured to convert incident photons into charge carriers; and
pixel circuitry coupled to the photosensitive medium and configured to create one or more imprints of an object in an image that is formed on the photosensitive medium, wherein each of the imprints persists over one or more image frames.
